(19) United States
(12) Patent Application Publication
(10) Pub. No.: US 2025/0176234 A1
(43) Pub. Date: May 29, 2025

(54) NITRIDE STRUCTURE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Toshiki HIKOSAKA, Kawasaki (JP); Hajime NAGO, Yokohama (JP); Jumpei TAJIMA, Mitaka (JP); Ryoma KANEKO, Ota (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/666,986

(22) Filed: May 17, 2024

(30) Foreign Application Priority Data
Nov. 29, 2023 (JP) 2023-201993

(51) Int. Cl. H01L 29/15; H01L 29/20; H01L 29/778

(52) U.S. Cl. CPC H10D 62/8161; H10D 30/475; H10D 62/8181; H10D 62/8503

(57) ABSTRACT

According to one embodiment, a nitride structure includes a base, a nitride member including Ga and N, and a stacked structure provided between the base and the nitride member in a first direction. The stacked structure includes a plurality of high composition films including Alₓ₁Ga₁₋ₓ₁N (0<x1≤1), and a plurality of low composition films including Alₓ₂Ga₁₋ₓ₂N (0≤x2<1, x2<x1). A high composition film thickness of one high composition film is thinner than a nitride member thickness of the nitride member in the first direction. A low composition film thickness of one of the plurality of low composition films in the first direction is thinner than the nitride member thickness. The high composition film and the low composition film are provided alternately along the first direction. The plurality of high composition films includes a first film and another film.

### CROSS-REFERENCE TO RELATED APPLICATIONS

This application is based upon and claims the benefit of priority from Japanese Patent Application No. 2023-201993, filed on Nov. 29, 2023; the entire contents of which are incorporated herein by reference.

### FIELD

Embodiments described herein relate generally to a nitride structure and a semiconductor device.

### BACKGROUND

For example, improved characteristics are desired in semiconductor devices based on nitride structures.

### BRIEF DESCRIPTION OF THE DRAWINGS

FIG. 1 is a schematic cross-sectional view illustrating a nitride structure according to a first embodiment;

FIG. 2 is a schematic cross-sectional view illustrating the nitride structure according to the first embodiment;

FIG. 3 is a schematic cross-sectional view illustrating the nitride structure according to the first embodiment;

FIG. 4 is an electron microscope image illustrating the nitride structure according to the first embodiment;

FIG. 5 is an electron microscope image illustrating the nitride structure according to the first embodiment;

FIG. 6 is a schematic cross-sectional view illustrating a semiconductor device according to a second embodiment; and

FIG. 7 is a schematic cross-sectional view illustrating a semiconductor device according to the second embodiment.

### DETAILED DESCRIPTION

According to one embodiment, a nitride structure includes a base, a nitride member including Ga and N, and a stacked structure provided between the base and the nitride member in a first direction. The stacked structure includes a plurality of high composition films including Alₓ₁Ga₁₋ₓ₁N (0<x1≤1), and a plurality of low composition films including Alₓ₂Ga₁₋ₓ₂N (0≤x2<1, x2<x1). A high composition film thickness of one of the plurality of high composition films in the first direction is thinner than a nitride member thickness of the nitride member in the first direction. A low composition film thickness of one of the plurality of low composition films in the first direction is thinner than the nitride member thickness. The high composition film and the low composition film are provided alternately along the first direction. The plurality of high composition films includes a first film and another film. The first film is provided between the base and the other film. The first film includes a first face region along a cross direction crossing the first direction, a first other face region along the cross direction, a first inclined region along a first inclined direction being inclined with respect to the first direction, and a first other inclined region along a first other inclined direction being inclined with respect to the first direction and crossing the first inclined direction. A direction from the first face region to the first other face region is along the cross direction. A position of the first inclined region in the cross direction is between a position of the first face region in the cross direction and a position of the first other face region in the cross direction. A position of the first other inclined region in the cross direction is between the position of the first inclined region in the cross direction and the position of the first other face region in the cross direction. A first inclined portion of the first inclined region is connected to the first face region. A first other inclined portion of the first other inclined region is connected to the first other face region. A position of the first connecting portion in the first direction is between a position of the base in the first direction and a position of the first face region in the first direction. The other film is along the crossing direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

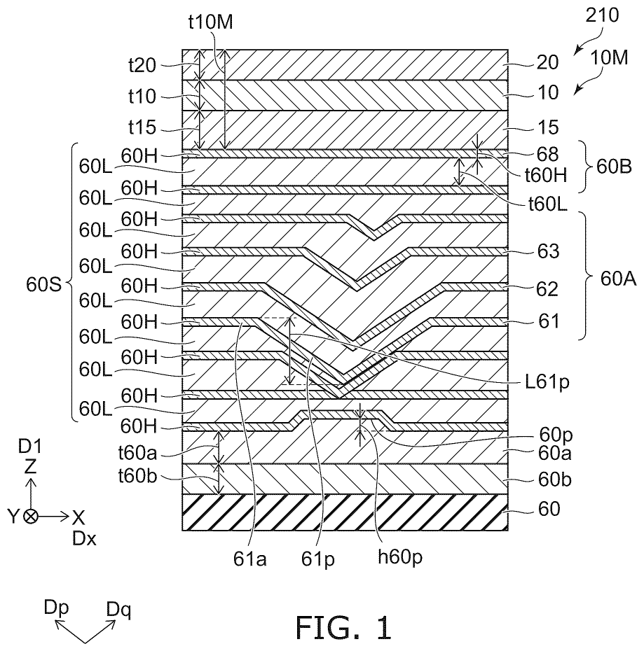

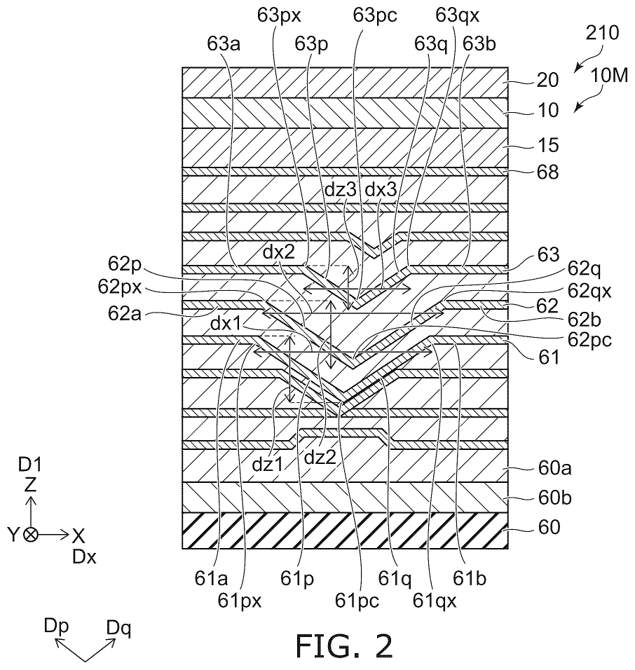

FIGS. 1 and 2 are schematic cross-sectional views illustrating a nitride structure according to a first embodiment.

As shown in FIG. 1, a nitride structure 210 according to the embodiment includes a base 60, a nitride member 10M, and a stacked structure 60S. The nitride member 10M includes Ga and N. The stacked structure 60S is provided between the base 60 and the nitride member 10M in a first direction D1.

The first direction D1 is defined as a Z-axis direction. One direction perpendicular to the Z-axis direction is defined as an X-axis direction. A direction perpendicular to the Z-axis direction and the X-axis direction is defined as a Y-axis direction. The base 60, the nitride member 10M, and the stacked structure 60S are in a layered form along the X-Y plane.

The stacked structure 60S includes a plurality of high composition films 60H and a plurality of low composition films 60L. The plurality of high composition films 60H include Alₓ₁Ga₁₋ₓ₁N (0<x1≤1). The plurality of low composition films 60L include Alₓ₂Ga₁₋ₓ₂N (0≤x2<1, x2<x1). In one example, the plurality of high composition films 60H are, for example, AlN films. The plurality of low composition films 60L are, for example, AlGaN films. The plurality of low composition films 60L may be, for example, GaN films.

A high composition film thickness t60H of one of the plurality of high composition films 60H in the first direction D1 is thinner than a nitride member thickness t10M of the nitride member 10M in the first direction. A low composition film thickness t60L of one of the plurality of low composition films 60L in the first direction D1 is thinner than the nitride member thickness t10M.

The nitride member 10M may include a plurality of layers. For example, the high composition film thickness t60H is thinner than a thickness of each of the plurality of layers along the first direction D1. For example, the low composition film thickness t60L is thinner than the thickness of each of the plurality of layers along the first direction D1.

For example, the nitride member 10M includes a first semiconductor layer 10 including Alₐ₁Ga₁₋ₐ₁N (0≤a1<1), and a second semiconductor layer 20 including Alₐ₂Ga₁₋ₐ₂N (0<a2≤1, a1<a2). The first semiconductor layer 10 is provided between the stacked structure 60S and the second semiconductor layer 20 in the first direction D1. The first semiconductor layer 10 is, for example, a GaN layer. The second semiconductor layer 20 is, for example, an AlGaN layer.

The first semiconductor layer 10 includes a portion facing the second semiconductor layer 20. A carrier region is formed in this portion. The carrier region is, for example, a two-dimensional electron gas. In a semiconductor device based on nitride structure 210, a carrier region is used for operation of the semiconductor device.

For example, the high composition film thickness t60H is thinner than a first semiconductor layer thickness t10 of the first semiconductor layer 10 in the first direction D1. For example, the high composition film thickness t60H is thinner than a second semiconductor layer thickness t20 of the second semiconductor layer 20 in the first direction D1. For example, the low composition film thickness t60L is thinner than the first semiconductor layer thickness t10. For example, the low composition film thickness t60L is thinner than the second semiconductor layer thickness t20.

In this example, the nitride member 10M further includes an intermediate semiconductor layer 15. The intermediate semiconductor layer 15 is provided between the stacked structure 60S and the first semiconductor layer 10. The intermediate semiconductor layer 15 includes, for example, Ga and N. The composition ratio of the intermediate semiconductor layer 15 may be the same as the composition ratio of the first semiconductor layer 10. The intermediate semiconductor layer 15 includes, for example, a first element (e.g., carbon). The first semiconductor layer 10 does not include the first element. Alternatively, a concentration of the first element in the first semiconductor layer 10 is lower than a concentration of the first element in the intermediate semiconductor layer 15.

The high composition film thickness t60H is thinner than an intermediate semiconductor layer thickness t15 of the intermediate semiconductor layer 15 in the first direction D1. The low composition film thickness t60L is thinner than the intermediate semiconductor layer thickness t15.

As shown in FIG. 1, for example, the high composition film 60H and the low composition film 60L are provided alternately along the first direction D1. For example, one of the plurality of high composition films 60H is provided between one of the plurality of low composition films 60L and another one of the plurality of low composition films 60L. For example, one of the plurality of low composition films 60L is provided between one of the plurality of high composition films 60H and another one of the plurality of high composition films 60H.

The stacked structure 60S is, for example, a superlattice stacked structure.

One of the plurality of high composition films 60H and the plurality of low composition films 60L includes a first film 61 and another film 68. Below, the plurality of high composition films include the first film 61 and the other film 68.

The first film 61 is provided between the base 60 and the other film 68. The first film 61 includes a V-shaped structure. The other film 68 includes a planar structure.

As described later, a direction of dislocation propagation changes in the V-shaped structure. By interacting a plurality of dislocations whose directions have changed, the dislocation density decreases. For example, a low dislocation density can be obtained in the nitride member 10M. According to the embodiments, a nitride structure with improved characteristics is obtained.

As shown in FIG. 1, for example, the depth of the V-shaped structure may decrease along the direction from the base 60 to the nitride member 10M. The V-shaped structure disappears in the other film 68.

For example, the stacked structure 60S includes a first portion 60A and a second portion 60B. The first portion 60A is provided between the base 60 and the second portion 60B. The high composition film 60H included in the first portion 60A includes a first face region 61a and a first inclined region 61p. The first face region 61a extends along a cross direction Dx crossing the first direction D1. The first inclined region 61p extends along a first inclined direction Dp that is inclined with respect to the first direction D1. The high composition film 60H included in the second portion 60B is along the cross direction Dx. The cross direction Dx may be substantially perpendicular to the first direction D1.

In the first inclined region 61p, the direction of dislocation propagation changes. By interacting a plurality of dislocations whose directions have changed, the dislocation density decreases. For example, a low dislocation density can be obtained in the nitride member 10M. According to the embodiments, a nitride structure with improved characteristics is obtained.

In the high composition film 60H included in the first portion 60A, a length L61p of the first inclined region 61p along the first direction D1 decreases in the direction from the base 60 to the second portion 60B.

As shown in FIG. 2, for example, the first film 61 includes the first face region 61a, a first other face region 61b, the first inclined region 61p, and a first other inclined region 61q. The first face region 61a extends along the cross direction Dx crossing the first direction D1. The cross direction Dx may be substantially perpendicular to the first direction D1. The first other face region 61b extends along the cross direction Dx. The first inclined region 61p extends along the first inclined direction Dp that is inclined with respect to the first direction D1. The first other inclined region 61q is along a first other inclined direction Dq that is inclined with respect to the first direction D1. The first other inclined region 61q is inclined with respect to the first direction D1 and crosses the first inclined direction Dp.

As shown in FIG. 2, a direction from the first face region 61a to the first other face region 61b is along the cross direction Dx. A position of the first inclined region 61p in the cross direction Dx is between a position of the first face region 61a in the cross direction Dx and a position of the first other face region 61b in the cross direction Dx. A position of the first other inclined region 61q in the cross direction Dx is between the position of the first inclined region 61p in the cross direction Dx and the position of the first other face region 61b in the cross direction Dx.

As shown in FIG. 2, a first inclined portion 61px of the first inclined region 61p is connected to the first face region 61a. A first other inclined portion 61qx of the first other inclined region 61q is connected to the first other face region 61b. A first connecting portion 61pc of the first inclined region 61p is connected to the first other inclined region 61q. The first connecting portion 61pc corresponds to the bottom of the V-shaped structure.

A position of the first connecting portion 61pc in the first direction D1 is between a position of the base 60 in the first direction D1 and a position of the first face region 61a in the first direction D1.

The other film 68 is along the cross direction Dx.

The direction of dislocation propagation changes in the first inclined region 61p and the first other inclined region 61q. By merging the plurality of dislocations whose directions have changed, the dislocation density decreases. For example, a low dislocation density can be obtained in the nitride member 10M.

For example, a part of one of the plurality of low composition films 60L is provided between the first inclined region 61p and the first other inclined region 61q in the cross direction Dx.

For example, the plurality of high composition films 60H further include a second film 62. The second film 62 is provided between the first film 61 and the other film 68 in the first direction D1. A part of the second film 62 is provided between the first inclined region 61p and the first other inclined region 61q in the cross direction Dx.

As shown in FIG. 2, the second film 62 includes a second face region 62a along the cross direction Dx, a second other face region 62b along the cross direction Dx, and a second inclined region 62p along the first inclined direction Dp, and a second other inclined region 62q along the first other inclined direction Dq.

A direction from the second face region 62a to the second other face region 62b is along the cross direction Dx. A position of the second inclined region 62p in the cross direction Dx is between a position of the second face region 62a in the cross direction Dx and a position of the second other face region 62b in the cross direction Dx. A position of the second other inclined region 62q in the cross direction Dx is between the position of the second inclined region 62p in the cross direction Dx and the position of the second other face region 62b in the cross direction Dx.

A second inclined portion 62px of the second inclined region 62p is connected to the second face region 62a. A second other inclined portion 62qx of the second other inclined region 62q is connected to the second other face region 62b. A second connecting portion 62pc of the second inclined region 62p is connected to the second other inclined region 62q. The second connecting portion 62pc corresponds to the bottom of the V-shaped structure.

A position of the second connecting portion 62pc in the first direction D1 is between the position of the first connecting portion 61pc in the first direction D1 and a position of the second face region 62a in the first direction D1.

The second face region 62a is located between the first face region 61a and the other film 68. The second other face region 62b is located between the first other face region 61b and the other film 68. The second inclined region 62p is located between the first inclined region 61p and the other film 68. The second other inclined region 62q is located between the first other inclined region 61q and the other film 68.

A part of the second inclined region 62p and a part of the second other inclined region 62q are located between the first inclined region 61p and the first other inclined region 61q in the cross direction Dx.

As shown in FIG. 2, for example, a distance along the cross direction Dx between the second inclined portion 62px and the second other inclined portion 62qx is defined as a distance dx2. A distance along the cross direction Dx between the first inclined portion 61px and the first other inclined portion 61qx is defined as a distance dx1. For example, the distance dx2 is shorter than the distance dx1. For example, the width of the V-shaped structure may decrease in the direction from the base 60 to the other film 68.

For example, a distance along the first direction D1 between the second connecting portion 62pc and the second face region 62a is defined as a second distance dz2. A distance along the first direction D1 between the first connecting portion 61pc and the first face region 61a is defined as a first distance dz1. For example, the second distance dz2 is shorter than the first distance dz1. For example, the depth of the V-shaped structure may decrease in the direction from the base 60 to the other film 68.

For example, a position of the second connecting portion 62pc in the cross direction Dx may be between a position of the first connecting portion 61pc in the cross direction Dx and a position of the first other inclined portion 61ax in the cross direction Dx. For example, a position of the second connecting portion 62pc in the cross direction Dx may be between the position of the first connecting portion 61pc in the cross direction Dx and a position of the first inclined portion 61px in the cross direction Dx.

The position of the second connecting portion 62pc in the cross direction Dx is between the position of the first connecting portion 61pc in the cross direction Dx and the position of the first other inclined portion 61qx in the cross direction Dx. This results in that the directions of more dislocations are likely to change in the second inclined region 62p and the second other inclined region 62q. Thereby, a low dislocation density can be easily obtained in the nitride member 10M.

The position of the second connecting portion 62pc in the cross direction Dx is between the position of the first connecting portion 61pc in the cross direction Dx and the position of the first inclined portion 61px in the cross direction Dx. This results in that the directions of more dislocations are likely to change in the second inclined region 62p and the second other inclined region 62q. Thereby, a low dislocation density can be easily obtained in the nitride member 10M.

The plurality of high composition films 60H may further include a third film 63. The third film 63 includes a third face region 63a along the cross direction Dx, a third other face region 63b along the cross direction Dx, a third inclined region 63p along the first inclined direction Dp, and a third other inclined region 63q along the first other inclined direction Dq.

The direction from the third face region 63a to the third other face region 63b is along the cross direction Dx. A position of the third inclined region 63p in the cross direction Dx is between a position of the third face region 63a in the cross direction Dx and a position of the third other face region 63b in the cross direction Dx. A position of the third other inclined region 63q in the cross direction Dx is between the position of the third inclined region 63p in the cross direction Dx and the position of the third other face region 63b in the cross direction Dx.

The third inclined portion 63px of the third inclined region 63p is connected to the third face region 63a. The third other inclined portion 63qx of the third other inclined region 63q is connected to the third other face region 63b. The third connecting portion 63pc of the third inclined region 63p is connected to the third other inclined region 63q. A position of the third connecting portion 63pc in the first direction D1 is between the position of the second connecting portion 62pc in the first direction D1 and a position of the third face region 63a in the first direction D1.

The third face region 63a is located between the second face region 62a and the other film 68. The third other face region 63b is located between the second other face region 62b and the other film 68. The third inclined region 63p is located between the second inclined region 62p and the other film 68. The third other inclined region 63q is located between the second other inclined region 62q and the other film 68.

As shown in FIG. 2, a distance along the first direction D1 between the third connecting portion 63pc and the third face region 63a is defined as a third distance dz3. As already described, the distance along the first direction D1 between the first connecting portion 61pc and the first face region 61a is defined as the first distance dz1. The third distance dz3 is shorter than the first distance dz1. As already explained, the distance along the first direction D1 between the second connecting portion 62pc and the second face region 62a is defined as the second distance dz2. The third distance dz3 may be shorter than the second distance dz2. The depth of the V-shaped structure may decrease in the direction from the base 60 to the other film 68.

For example, a distance along the cross direction Dx between the third inclined portion 63px and the third other inclined portion 63qx is defined as a distance dx3. The distance dx3 is shorter than the distance dx1. The distance dx3 may be shorter than the distance dx2. The width of the V-shaped structure may decrease in the direction from the base 60 to the other film 68.

For example, a direction from the first inclined region 61p to the third inclined region 63p is along the first direction D1. A direction from the first other inclined region 61q to the third other inclined region 63q is along the first direction D1.

For example, a position of the third connecting portion 63pc in the cross direction Dx may be between the position of the second connecting portion 62pc in the cross direction Dx and the position of the second other inclined portion 62qx in the cross direction Dx. For example, the position of the third connecting portion 63pc in the cross direction Dx may be between the position of the second connecting portion 62pc in the cross direction Dx and the position of the second inclined portion 62px in the cross direction Dx.

The position of the third connecting portion 63pc in the cross direction Dx is between the position of the second connecting portion 62pc in the cross direction Dx and the position of the second other inclined portion 62qx in the cross direction Dx. This results in that the directions of more dislocations are likely to change in the third inclined region 63p and the third other inclined region 63q. Thereby, a low dislocation density can be easily obtained in the nitride member 10M.

The position of the third connecting portion 63pc in the cross direction Dx is between the position of the second connecting portion 62pc in the cross direction Dx and the position of the second inclined portion 62px in the cross direction Dx. This results in that the directions of more dislocations are likely to change in the third inclined region 63p and the third other inclined region 63q. Thereby, a low dislocation density can be easily obtained in the nitride member 10M.

For example, the position of the second connecting portion 62pc in the cross direction Dx may be between the position of the third connecting portion 63pc in the cross direction Dx and the position of the first connecting portion 61pc in the cross direction Dx.

The position of the second connecting portion 62pc in the cross direction Dx is between the position of the third connecting portion 63pc in the cross direction Dx and the position of the first connecting portion 61pc in the cross direction Dx. This results in that the directions of more dislocations are likely to change in the third inclined region 63p and the third other inclined region 63q. Thereby, a low dislocation density can be easily obtained in the nitride member 10M.

As shown in FIG. 1, the nitride structure 210 may further include a first intermediate layer 60a. The first intermediate layer 60a is provided between the base 60 and the stacked structure 60S. The first intermediate layer 60a includes, for example, Al_{z1}Ga_{1-z1}N (0<z1<1). The first intermediate layer 60a is, for example, an AlGaN layer. The first intermediate layer 60a includes a protrusion 60p that protrudes toward the stacked structure 60S. A direction from at least a part of the protrusion 60p to the first connecting portion 61pc is along the first direction D1. For example, at least a part of the protrusion 60p may overlap the first inclined region 61p in the first direction D1. For example, at least a part of the protrusion 60p may overlap the first other inclined region 61q in the first direction D1.

By providing the protrusion 60p, a V-shaped structure is easily formed. By providing the protrusion 60p, the first inclined region 61p and the first other inclined region 61q are easily formed. In these inclined regions, the direction of dislocation propagation changes. Thereby, a low dislocation density can be obtained in the nitride member 10M.

A height h60p (see FIG. 1) of the protrusion 60p may be, for example, not less than 5 nm and not more than 200 nm.

As shown in FIG. 1, the nitride structure 210 may further include a second intermediate layer 60b. The second intermediate layer 60b is provided between the base 60 and the first intermediate layer 60a. The second intermediate layer 60b includes Al_{z2}Ga_{1-z2}N (0<z2≤1). The second intermediate layer 60b may be, for example, an AlN layer.

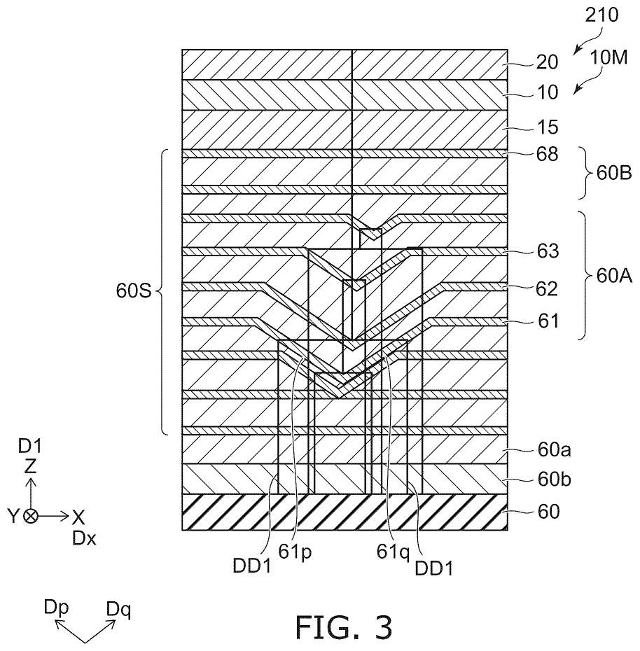

FIG. 3 is a schematic cross-sectional view illustrating the nitride structure according to the first embodiment.

As shown in FIG. 3, the stacked structure 60S includes a plurality of dislocations DD1. One of the plurality of dislocations DD1 passes through the first inclined region 61p. Another one of the plurality of dislocations DD1 passes through the first other inclined region 61q. A direction of one of the plurality of dislocations DD1 changes in the first inclined region 61p. A direction of another one of the plurality of dislocations DD1 changes in the first other inclined region 61q. The dislocation DD1 passing through the first inclined region 61p merges with the dislocation DD1 passing through the first other inclined region 61q. This reduces the number of plurality of dislocations DD1. The inclined region reduces dislocation density.

For example, the density of the plurality of dislocations DD1 reaching the other film 68 decreases. For example, the density of dislocations DD1 passing through the other film 68 is lower than the density of dislocations DD1 passing through the first film 61. For example, a low dislocation density can be obtained in the nitride member 10M.

For example, the high composition film thickness t60H is not less than 3 nm and not more than 20 nm. For example, the low composition film thickness t60L is not less than 5 nm and not more than 50 nm. For example, the nitride member thickness t10M is not less than 50 nm and not more than 3000 nm.

For example, the first semiconductor layer thickness t10 is not less than 50 nm and not more than 2000 nm. For example, the second semiconductor layer thickness t20 is not less than 10 nm and not more than 50 nm. For example, the intermediate semiconductor layer thickness t15 is not less than 100 nm and not more than 2000 nm.

For example, the nitride member thickness t10M may be not less than 10 times and not more than 1000 times the high composition film thickness t60H. For example, the nitride member thickness t10M may be not less than 2 times and not more than 600 times the low composition film thickness t60L.

For example, the first semiconductor layer thickness t10 may be not less than 10 times and not more than 1000 times the high composition film thickness t60H. For example, the first semiconductor layer thickness t10 may be not less than 2 times and not more than 600 times the low composition film thickness t60L.

For example, the second semiconductor layer thickness t20 may be not less than 2 times and not more than 20 times the high composition film thickness t60H. For example, the second semiconductor layer thickness t20 may be not less than 2 times and not more than 10 times the low composition film thickness t60L.

For example, the intermediate semiconductor layer thickness t15 may be not less than 10 times and not more than 1000 times the high composition film thickness t60H. For example, the intermediate semiconductor layer thickness t15 may be not less than 2 times and not more than 600 times the low composition film thickness t60L.

For example, the position of the second connecting portion 62pc in the cross direction Dx may be between the position of the first connecting portion 61pc in the cross direction Dx and the position of the first other inclined portion 61qx in the cross direction Dx. For example, the position of the second connecting portion 62pc in the cross direction Dx may be between the position of the first connecting portion 61pc in the cross direction Dx and the position of the first inclined portion 61px in the cross direction Dx. As a result, the direction of propagation of the dislocations that have merged in the first inclined region 61p or the first other inclined region 61q changes again in the second inclined region 62p or the second other inclined region 62q. By interacting the plurality of dislocations whose directions have changed, the dislocation density further decreases. Thereby, a further lower dislocation density can be easily obtained in the nitride member 10M.

For example, the position of the second connecting portion 62pc in the cross direction Dx may be between the position of the third connecting portion 63pc in the cross direction Dx and the position of the first connecting portion 61pc in the cross direction Dx. As a result, the direction of propagation of the dislocations that have merged in the first inclined region 61p or the first other inclined region 61q changes again in the second inclined region 62p or the second other inclined region 62q. By interacting the plurality of dislocations whose directions have changed, the dislocation density further decreases. Thereby, a further lower dislocation density can be easily obtained in the nitride member 10M.

In the embodiment, one of the plurality of high composition films 60H may be in contact with the nitride member 10M. Alternatively, one of the plurality of low composition films 60L may be in contact with the nitride member 10M. One of the plurality of high composition films 60H may be in contact with the first intermediate layer 60a. Alternatively, one of the plurality of low composition films 60L may be in contact with the first intermediate layer 60a.

The number of the plurality of high composition films 60H may be, for example, not less than 4 and not more than 200. The number of the plurality of low composition films 60L may be, for example, not less than 4 and not more than 200.

For example, the other film 68 of the plurality of high composition films 60H may be closest to the nitride member 10M among the plurality of high composition films 60H. In the embodiment, the V-shaped structure disappears in the second portion 60B of the stacked structure 60S. For example, the other films 68 of the plurality of high composition films 60H is along the cross direction Dx, and do not include a V-shaped structure.

For example, a first reference example can be considered in which the V-shaped structure does not disappear in the stacked structure 60S. In the first reference example, the V-shaped structure is buried in the nitride member 10M. In the first reference example, it is difficult to reduce dislocations. For example, the dislocation density in the nitride member 10M of the first reference example is 1.6×10¹⁰/cm². The insulation of the stacked structure 60S is likely to deteriorate. Current tends to flow in the V-shaped structure, and current leakage tends to occur. The breakdown voltage tends to decrease.

In contrast, in the embodiment, the V-shaped structure disappears in the other films 68 included in the plurality of high composition films 60H. This makes it easier to obtain a lower dislocation density. It becomes easy to obtain high insulation characteristics. It is easy to obtain high breakdown voltage.

On the other hand, a second reference example can be considered in which the stacked structure 60S does not include a V-shaped structure. In the second reference example, it is difficult to reduce dislocations. For example, the dislocation density in the nitride member 10M of the second reference example is 2.0×10¹⁰/cm². On the other hand, in the embodiment in which the stacked structure 60S has the V-shaped structure, the dislocation density in the nitride member 10M is 1.0×10¹⁰/cm².

In the embodiment, for example, the conditions for forming at least a part of the first portion 60A of the stacked structure 60S are different from the conditions for forming the second portion 60B of the stacked structure 60S. For example, when the temperature in the film formation is low, the V-shaped structure (inclined region) is more likely to be formed than when the temperature is high. For example, when the V/III ratio in the film formation is low, the V-shaped structure (inclined region) is more likely to be formed than when the V/III ratio is high. By changing such formation conditions, the above-mentioned stacked structure 60S can be obtained. The V/III ratio is the ratio of the amount of Group V raw material supplied to the amount of Group III raw material supplied. In the first portion 60A, at least one of the temperature and the V/III ratio during film formation may be changed. For example, V-shaped structures are easily changed.

In one example, the temperature at which the first film 61 is formed is lower than the temperature at which the other film 68 is formed. In one example, the V/III ratio when the first film 61 is formed is lower than the V/III ratio when the other film 68 is formed.

In the embodiment, the length along the first direction D1 of the first portion 60A in which the V-shaped structure changes may be shorter than the length along the first direction D1 of the second portion 60B which does not include the V-shaped structure. For example, by making the length of the first portion 60A along the first direction D1 shorter than the length of the second portion 60B along the first direction D1, high insulation characteristics can be easily obtained. For example, it is easy to obtain a high breakdown voltage.

In the embodiment, another one or more of the plurality of high composition films 60H may be provided between the first intermediate layer 60a and the first film 61. Another one or more of the plurality of high composition films 60H may be provided between the first film 61 and the second film 62. Another one or more of the plurality of high composition films 60H may be provided between the second film 62 and the third film 63. Another one or more of the plurality of high composition films 60H may be provided between the third film 63 and the other film 68. A plurality of other films 68 may be provided.

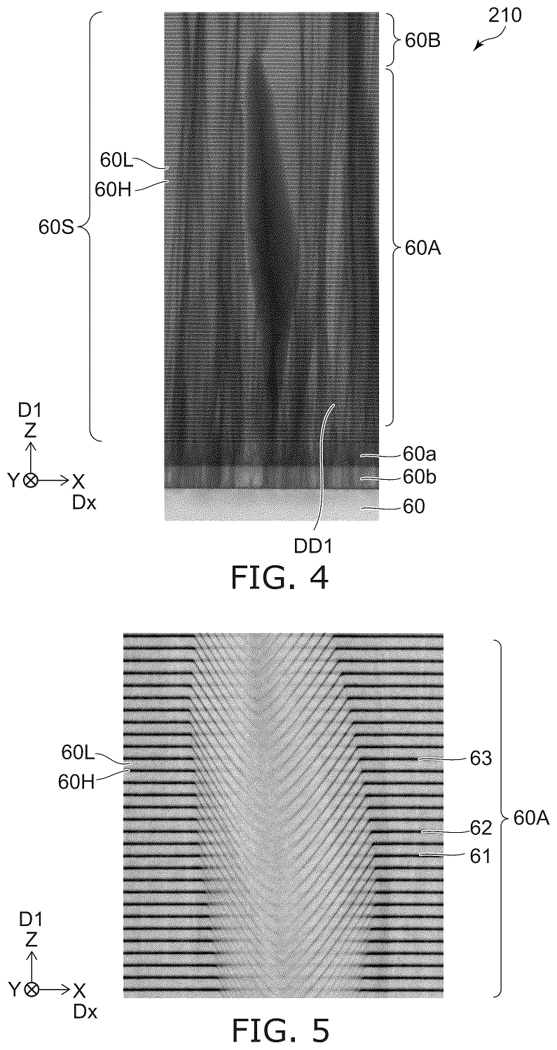

FIGS. 4 and 5 are electron microscope images illustrating the nitride structure according to the first embodiment.

These figures are TEM (Transmission Electron Microscope) images of one sample of the nitride structure 210. As shown in FIG. 4, the length of the first portion 60A along the first direction D1 may be longer than the length of the second portion 60B along the first direction D1. By the length of the first portion 60A along the first direction D1 being longer than the length of the second portion 60B along the first direction D1, it is easier to obtain a lower dislocation density. As shown in FIG. 5, at least a part of the V-shaped structure may be curved.

In the embodiment, the base 60 may be, for example, a silicon substrate. The base 60 may include, for example, sapphire, SiC, or GaN.

For example, the concentration of oxygen in the first intermediate layer 60a may be lower than the concentration of oxygen in the stacked structure 60S. The concentration of oxygen in the first intermediate layer 60a may be, for example, not less than 3×10¹⁴/cm³ and not more than 4×10¹⁶/cm³. For example, the protrusion 60p is likely to be formed. It becomes easy to obtain high insulation characteristics.

For example, the concentration of carbon in the first intermediate layer 60a may be higher than the concentration of carbon in the stacked structure 60S. The concentration of carbon in the first intermediate layer 60a may be, for example, not less than 1×10¹⁹/cm³ and not more than 8×10¹⁹/cm³. For example, the protrusion 60p is likely to be formed. It becomes easy to obtain low dislocation density.

### Second Embodiment

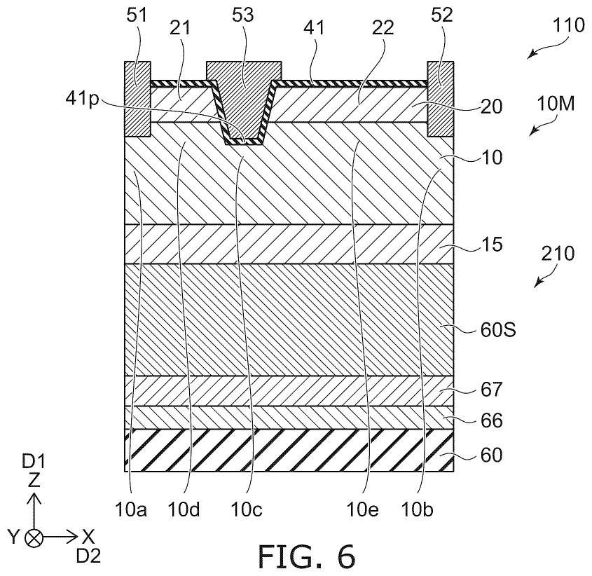

FIG. 6 is a schematic cross-sectional view illustrating a semiconductor device according to the second embodiment.

As shown in FIG. 6, a semiconductor device 110 according to the embodiment includes the nitride structure 210 according to the first embodiment, a first electrode 51, a second electrode 52, and a third electrode 53.

As already described, the nitride member 10M includes the first semiconductor layer 10 and the second semiconductor layer 20. The nitride member 10M may further include the intermediate semiconductor layer 15. The intermediate semiconductor layer 15 may be provided as necessary or may be omitted.

A second direction D2 from the first electrode 51 to the second electrode 52 crosses the first direction D1. The second direction D2 may be, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 21 and a second semiconductor portion 22. A direction from the first semiconductor portion 21 to the second semiconductor portion 22 is along the second direction D2. The first electrode 51 is electrically connected to the first semiconductor portion 21. The second electrode 52 is electrically connected to the second semiconductor portion 22.

A current flowing between the first electrode 51 and the second electrode 52 is controlled by a potential of the third electrode 53. The potential of the third electrode 53 may be, for example, a potential based on a potential of the first electrode 51. The first electrode 51 functions, for example, as a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

The semiconductor device 110 includes the stacked structure 60S of nitride structures 210 according to the first embodiment. Good crystalline quality can be obtained in the semiconductor device 110. For example, lower dislocation densities are obtained.

As shown in FIG. 6, in this example, at least a part of the third electrode 53 is provided between the first semiconductor portion 21 and the second semiconductor portion 22 in the second direction D2. The third electrode 53 is, for example, a recessed gate electrode.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A position of the fourth partial region 10d in the second direction D2 is between a position of the first partial region 10a in the second direction D2 and a position of the third partial region 10c in the second direction D2. A position of the fifth partial region 10e in the second direction D2 is between the position of the third partial region 10c in the second direction D2 and a position of the second partial region 10b in the second direction D2.

A direction from the fourth partial region 10d to the first semiconductor portion 21 is along the first direction D1. A direction from the fifth partial region 10e to the second semiconductor portion 22 is along the first direction D1. In this example, a part of the third electrode 53 is located between the fourth partial region 10d and the fifth partial region 10e in the second direction D2. A high threshold voltage can be obtained. For example, normally-off operation is obtained.

As shown in FIG. 6, the semiconductor device 110 may further include a first insulating member 41. The first insulating member 41 includes a first insulating portion 41p. The first insulating portion 41p is provided between the third electrode 53 and the nitride member 10M. The first insulating portion 41p functions, for example, as a gate insulating film.

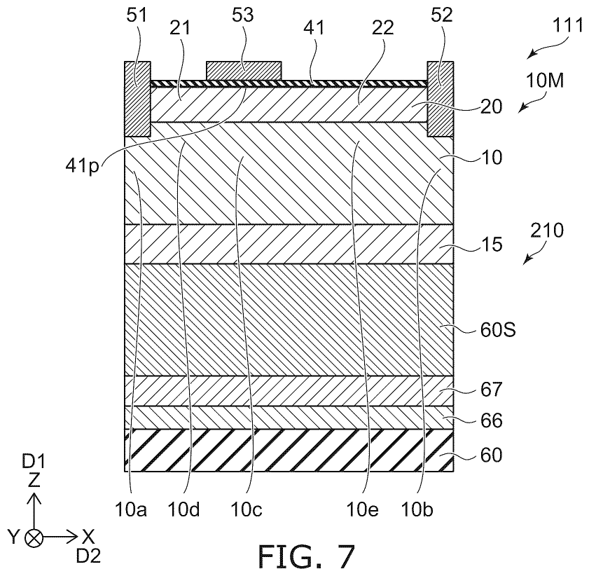

FIG. 7 is a schematic cross-sectional view illustrating a semiconductor device according to the second embodiment.

As shown in FIG. 7, a semiconductor device 111 according to the embodiment includes the nitride structure 210 according to the first embodiment, the first electrode 51, the second electrode 52, and the third electrode 53. In the semiconductor device 111, the third electrode 53 does not overlap the second semiconductor layer 20 in the second direction D2. The configuration of the semiconductor device 111 other than this may be the same as that of the semiconductor device 110.

The semiconductor device 111, a normally-on operation can be obtained, for example. In the semiconductor device 111, the first insulating member 41 may be omitted. For example, the device may be used as a high frequency switching element.

In the embodiment, information regarding the shape of the nitride region, etc. can be obtained, for example, by electron microscopic observation. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by X-ray diffraction measurement or Reciprocal Space Mapping.

Embodiments may include the following Technical proposals:

### (Technical Proposal 1)

A nitride structure, comprising:
a base;
a nitride member including Ga and N; and
a stacked structure provided between the base and the nitride member in a first direction,
the stacked structure including
   a plurality of high composition films including Alₓ₁Ga₁₋ₓ₁N (0<x1≤1), and
   a plurality of low composition films including Alₓ₂Ga₁₋ₓ₂N (0≤x2<1, x2<x1),
a high composition film thickness of one of the plurality of high composition films in the first direction being thinner than a nitride member thickness of the nitride member in the first direction,
a low composition film thickness of one of the plurality of low composition films in the first direction being thinner than the nitride member thickness,
the high composition film and the low composition film being provided alternately along the first direction,
the plurality of high composition films including a first film and another film, the first film being provided between the base and the other film,
the first film including
   a first face region along a cross direction crossing the first direction,
   a first other face region along the cross direction,
   a first inclined region along a first inclined direction being inclined with respect to the first direction, and
   a first other inclined region along a first other inclined direction being inclined with respect to the first direction and crossing the first inclined direction,
a direction from the first face region to the first other face region being along the cross direction,
a position of the first inclined region in the cross direction being between a position of the first face region in the cross direction and a position of the first other face region in the cross direction,
a position of the first other inclined region in the cross direction being between the position of the first inclined region in the cross direction and the position of the first other face region in the cross direction,
a first inclined portion of the first inclined region being connected to the first face region,
a first other inclined portion of the first other inclined region being connected to the first other face region,
a position of the first connecting portion in the first direction being between a position of the base in the first direction and a position of the first face region in the first direction, and
the other film being along the crossing direction.

### (Technical Proposal 2)

The nitride structure according to Technical proposal 1, wherein
a part of one of the plurality of low composition films is provided between the first inclined region and the first other inclined region in the cross direction.

### (Technical Proposal 3)

The nitride structure according to Technical proposal 2, wherein
the plurality of high composition films further include a second film,
the second film is provided between the first film and the other film in the first direction, and
a part of the second film is provided between the first inclined region and the first other inclined region in the cross direction.

### (Technical Proposal 4)

The nitride structure according to Technical proposal 2, wherein
the plurality of high composition films further include a second film,
the second film includes
   a second face region along the cross direction,
   a second other face region along the cross direction,
   a second inclined region along the first inclined direction, and
   a second other inclined region along the first other inclined direction,
a direction from the second face region to the second other face region is along the cross direction,
a position of the second inclined region in the cross direction is between a position of the second face region in the cross direction and a position of the second other face region in the cross direction,
a position of the second other inclined region in the cross direction is between the position of the second inclined region in the cross direction and the position of the second other face region in the cross direction,
a second inclined portion of the second inclined region is connected to the second face region,
a second other inclined portion of the second other inclined region is connected to the second other face region,
a second connecting portion of the second inclined region is connected to the second other inclined region,
a position of the second connecting portion in the first direction is between the position of the first connecting portion in the first direction and a position of the second face region in the first direction,
the second face region is between the first face region and the other film,
the second other face region is between the first other face region and the other film,
the second inclined region is between the first inclined region and the other film,
the second other inclined region is between the first other inclined region and the other film, and
a part of the second inclined region and a part of the second other inclined region are located between the first inclined region and the first other inclined region in the cross direction.

### (Technical Proposal 5)

The nitride structure according to Technical proposal 4, wherein
a distance along the cross direction between the second inclined portion and the second other inclined portion is shorter than a distance along the cross direction between the first inclined portion and the first inclined portion.

### (Technical Proposal 6)

The nitride structure according to Technical proposal 4 or 5, wherein
a second distance along the first direction between the second connecting portion and the second face region is shorter than a first distance along the first direction between the first connecting portion and the first face region.

### (Technical Proposal 7)

The nitride structure according to Technical proposal 4, wherein
a position of the second connecting portion in the cross direction is between the position of the first connecting portion in the cross direction and the position of the first other inclined portion in the cross direction, or
the position of the second connecting portion in the cross direction is between the position of the first connecting portion in the cross direction and the position of the first inclined portion in the cross direction.

### (Technical Proposal 8)

The nitride structure according to Technical proposal 4, wherein
the plurality of high composition films further include a third film,
the third film includes
   a third face region along the cross direction,
   a third other face region along the cross direction,
   a third inclined region along the first inclined direction, and
   a third other inclined region along the first other inclined direction,
a direction from the third face region to the third other face region is along the cross direction,
a position of the third inclined region in the cross direction is between a position of the third face region in the cross direction and a position of the third other face region in the cross direction,
a position of the third other inclined region in the cross direction is between the position of the third inclined region in the cross direction and the position of the third other face region in the cross direction,
a third inclined portion of the third inclined region is connected to the third face region,
a third other inclined portion of the third other inclined region is connected to the third other face region,
a third connecting portion of the third inclined region is connected to the third other inclined region,
a position of the third connecting portion in the first direction is between the position of the second connecting portion in the first direction and a position of the third face region in the first direction,
the third face region is between the second face region and the other film,
the third other face region is between the second other face region and the other film,
the third inclined region is between the second inclined region and the other film,
the third other inclined region is between the second other inclined region and the other film, and
a third distance along the first direction between the third connecting portion and the third face region is shorter than a first distance along the first direction between the first connecting portion and the first face region.

### (Technical Proposal 9)

The nitride structure according to Technical proposal 8, wherein
a direction from the first inclined region to the third inclined region is along the first direction.

### (Technical Proposal 10)

The nitride structure according to any one of Technical proposals 1-9, further comprising:
a first intermediate layer provided between the base and the stacked structure, the first intermediate layer including Al_{z1}Ga_{1-z1}N (0<z1<1),
the first intermediate layer including a protrusion protruding toward the stacked structure, and
a direction from at least a part of the protrusion to the first connecting portion being along the first direction.

### (Technical Proposal 11)

The nitride structure according to any one of Technical proposals 1-10, wherein
a dislocation passing through the first inclined region merges with a dislocation passing through the first other inclined direction.

### (Technical Proposal 12)

The nitride structure according to any one of Technical proposals 1-10, wherein
a density of dislocations passing through the other film is lower than a density of dislocations passing through the first film.

### (Technical Proposal 13)

A nitride structure, comprising:
a base;
a nitride member including Ga and N; and
a stacked structure provided between the base and the nitride member in a first direction,
the stacked structure including
   a plurality of high composition films including Alₓ₁Ga₁₋ₓ₁N (0<x1≤1), and
   a plurality of low composition films including Alₓ₂Ga₁₋ₓ₂N (0≤x2<1, x2<x1),
a high composition film thickness of one of the plurality of high composition films in the first direction being thinner than a nitride member thickness of the nitride member in the first direction,
a low composition film thickness of one of the plurality of low composition films in the first direction being thinner than the nitride member thickness,
the high composition film and the low composition film being provided alternately along the first direction,
the stacked structure including a first portion and a second portion,
the first portion being provided between the base and the second portion, and
the high composition film included in the first portion including a first face region along a cross direction crossing the first direction, and a first inclined region along a first inclined direction inclined with respect to the first direction.

### (Technical Proposal 14)

The nitride structure according to Technical proposal 13, wherein
in the high composition film included in the first portion, a length of the first inclined region along the first direction decreases in a direction from the base to the second portion.

### (Technical Proposal 15)

The nitride structure according to Technical proposal 13 or 14, wherein
in the high composition film included in the first portion, a length of the first inclined region along the cross direction decreases in a direction from the base to the second portion.

### (Technical Proposal 16)

The nitride structure according to Technical proposal 13 or 14, further comprising:
a first intermediate layer provided between the base and the stacked structure, the first intermediate layer including Al_{z1}Ga_{1-z1}N (0<z1<1),
the first intermediate layer including a protrusion protruding toward the stacked structure, and
at least a part of the protrusion overlapping the first inclined region in the first direction.

### (Technical Proposal 17)

The nitride structure according to Technical proposal 10 or 16, further comprising:
a second intermediate layer provided between the base body and the first intermediate layer, the second intermediate layer including Al_{z2}Ga_{1-z2}N (0<z2≤1).

### (Technical Proposal 18)

The nitride structure according to any one of Technical proposals 10-17, wherein
the nitride member includes
   a first semiconductor layer including Alₐ₁Ga₁₋ₐ₁N (0≤a1<1), and
   a second semiconductor layer including Alₐ₂Ga₁₋ₐ₂N (0<a2≤1, a1<a2), and
the first semiconductor layer is provided between the stacked body and the second semiconductor layer in the first direction.

### (Technical Proposal 19)

A semiconductor device, comprising:
the nitride structure according to any one of Technical proposals 1-17;
a first electrode;
a second electrode; and
a third electrode,
the nitride member including
   a first semiconductor layer including Alₐ₁Ga₁₋ₐ₁N (0≤a1<1), and
   a second semiconductor layer including Alₐ₂Ga₁₋ₐ₂N (0<a2≤1, a1<a2), and
the first semiconductor layer being provided between the stacked body and the second semiconductor layer in the first direction,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

### (Technical Proposal 20)

The semiconductor device according to Technical proposal 19, further comprising:
a first insulating member including a first insulating portion, and
the first insulating portion being provided between the third electrode and the nitride member.

### (Technical Proposal 21)

The nitride structure according to Technical proposal 8 or 9, wherein
a position of the second connecting portion in the cross direction is between the position of the first connecting portion in the cross direction and the position of the third connecting portion in the cross direction.

### (Technical Proposal 22)

The nitride structure according to any one of Technical proposals 1-18, wherein
the high composition film thickness is not less than 3 nm and not more than 20 nm,
the low composition film thickness is not less than 5 nm and not more than 50 nm, and
the nitride member thickness is not less than 50 nm and not more than 3000 nm.

### (Technical Proposal 23)

The semiconductor device according to Technical proposal 19 or 20, wherein
at least a portion of the third electrode is provided between the first semiconductor portion and the second semiconductor portion in the second direction.

According to the embodiment, it is possible to provide a nitride structure and a semiconductor device whose characteristics can be improved.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

In the specification, “state of being electrically connected” includes a state in which a plurality of conductors are physically in contact with each other and a current flows between the plurality of conductors. The “state of being electrically connected” includes a state in which another conductor is inserted between the plurality of conductors and a current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the nitride structure such as nitride regions, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nitride structures and all semiconductor devices practicable by an appropriate design modification by one skilled in the art based on the nitride structures and semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride structure, comprising:
a base;
a nitride member including Ga and N; and
a stacked structure provided between the base and the nitride member in a first direction,
the stacked structure including
a plurality of high composition films including Alₓ₁Ga₁₋ₓ₁N (0<x1≤1), and
a plurality of low composition films including Alₓ₂Ga₁₋ₓ₂N (0≤x2<1, x2<x1),
a high composition film thickness of one of the plurality of high composition films in the first direction being thinner than a nitride member thickness of the nitride member in the first direction,
a low composition film thickness of one of the plurality of low composition films in the first direction being thinner than the nitride member thickness,
the high composition film and the low composition film being provided alternately along the first direction,
the plurality of high composition films including a first film and another film, the first film being provided between the base and the other film,
the first film including
a first face region along a cross direction crossing the first direction,
a first other face region along the cross direction,
a first inclined region along a first inclined direction being inclined with respect to the first direction, and
a first other inclined region along a first other inclined direction being inclined with respect to the first direction and crossing the first inclined direction,
a direction from the first face region to the first other face region being along the cross direction,
a position of the first inclined region in the cross direction being between a position of the first face region in the cross direction and a position of the first other face region in the cross direction,
a position of the first other inclined region in the cross direction being between the position of the first inclined region in the cross direction and the position of the first other face region in the cross direction,
a first inclined portion of the first inclined region being connected to the first face region,
a first other inclined portion of the first other inclined region being connected to the first other face region,
a position of the first connecting portion in the first direction being between a position of the base in the first direction and a position of the first face region in the first direction, and
the other film being along the crossing direction.

2. The structure according to claim 1, wherein
a part of one of the plurality of low composition films is provided between the first inclined region and the first other inclined region in the cross direction.

3. The structure according to claim 2, wherein
the plurality of high composition films further include a second film,
the second film is provided between the first film and the other film in the first direction, and
a part of the second film is provided between the first inclined region and the first other inclined region in the cross direction.

4. The structure according to claim 2, wherein
the plurality of high composition films further include a second film,
the second film includes
a second face region along the cross direction,
a second other face region along the cross direction,
a second inclined region along the first inclined direction, and
a second other inclined region along the first other inclined direction,
a direction from the second face region to the second other face region is along the cross direction,
a position of the second inclined region in the cross direction is between a position of the second face region in the cross direction and a position of the second other face region in the cross direction,
a position of the second other inclined region in the cross direction is between the position of the second inclined region in the cross direction and the position of the second other face region in the cross direction,
a second inclined portion of the second inclined region is connected to the second face region,
a second other inclined portion of the second other inclined region is connected to the second other face region,
a second connecting portion of the second inclined region is connected to the second other inclined region,
a position of the second connecting portion in the first direction is between the position of the first connecting portion in the first direction and a position of the second face region in the first direction,
the second face region is between the first face region and the other film,
the second other face region is between the first other face region and the other film,
the second inclined region is between the first inclined region and the other film,
the second other inclined region is between the first other inclined region and the other film, and
a part of the second inclined region and a part of the second other inclined region are located between the first inclined region and the first other inclined region in the cross direction.

5. The structure according to claim 4, wherein
a distance along the cross direction between the second inclined portion and the second other inclined portion is shorter than a distance along the cross direction between the first inclined portion and the first inclined portion.

6. The structure according to claim 4, wherein
a second distance along the first direction between the second connecting portion and the second face region is shorter than a first distance along the first direction between the first connecting portion and the first face region.

7. The structure according to claim 4, wherein
a position of the second connecting portion in the cross direction is between the position of the first connecting portion in the cross direction and the position of the first other inclined portion in the cross direction, or
the position of the second connecting portion in the cross direction is between the position of the first connecting portion in the cross direction and the position of the first inclined portion in the cross direction.

8. The structure according to claim 4, wherein
the plurality of high composition films further include a third film,
the third film includes
a third face region along the cross direction,
a third other face region along the cross direction,
a third inclined region along the first inclined direction, and
a third other inclined region along the first other inclined direction,
a direction from the third face region to the third other face region is along the cross direction,
a position of the third inclined region in the cross direction is between a position of the third face region in the cross direction and a position of the third other face region in the cross direction,
a position of the third other inclined region in the cross direction is between the position of the third inclined region in the cross direction and the position of the third other face region in the cross direction,
a third inclined portion of the third inclined region is connected to the third face region,
a third other inclined portion of the third other inclined region is connected to the third other face region,
a third connecting portion of the third inclined region is connected to the third other inclined region,
a position of the third connecting portion in the first direction is between the position of the second connecting portion in the first direction and a position of the third face region in the first direction,
the third face region is between the second face region and the other film,
the third other face region is between the second other face region and the other film,
the third inclined region is between the second inclined region and the other film,
the third other inclined region is between the second other inclined region and the other film, and
a third distance along the first direction between the third connecting portion and the third face region is shorter than a first distance along the first direction between the first connecting portion and the first face region.

9. The structure according to claim 8, wherein
a direction from the first inclined region to the third inclined region is along the first direction.

10. The structure according to claim 1, further comprising:
a first intermediate layer provided between the base and the stacked structure, the first intermediate layer including Al_{z1}Ga_{1-z1}N (0<z1<1),
the first intermediate layer including a protrusion protruding toward the stacked structure, and
a direction from at least a part of the protrusion to the first connecting portion being along the first direction.

11. The structure according to claim 1, wherein
a dislocation passing through the first inclined region merges with a dislocation passing through the first other inclined direction.

12. The structure according to claim 1, wherein
a density of dislocations passing through the other film is lower than a density of dislocations passing through the first film.

13. A nitride structure, comprising:
a base;
a nitride member including Ga and N; and
a stacked structure provided between the base and the nitride member in a first direction,
the stacked structure including
a plurality of high composition films including Alₓ₁Ga₁₋ₓ₁N (0<x1≤1), and
a plurality of low composition films including Alₓ₂Ga₁₋ₓ₂N (0≤x2<1, x2<x1),
a high composition film thickness of one of the plurality of high composition films in the first direction being thinner than a nitride member thickness of the nitride member in the first direction,
a low composition film thickness of one of the plurality of low composition films in the first direction being thinner than the nitride member thickness,
the high composition film and the low composition film being provided alternately along the first direction,
the stacked structure including a first portion and a second portion,
the first portion being provided between the base and the second portion, and
the high composition film included in the first portion including a first face region along a cross direction crossing the first direction, and a first inclined region along a first inclined direction inclined with respect to the first direction.

14. The structure according to claim 13, wherein
in the high composition film included in the first portion, a length of the first inclined region along the first direction decreases in a direction from the base to the second portion.

15. The structure according to claim 13, wherein
in the high composition film included in the first portion, a length of the first inclined region along the cross direction decreases in a direction from the base to the second portion.

16. The structure according to claim 13, further comprising:
a first intermediate layer provided between the base and the stacked structure, the first intermediate layer including Al_{z1}Ga_{1-z1}N (0<z1<1),
the first intermediate layer including a protrusion protruding toward the stacked structure, and
at least a part of the protrusion overlapping the first inclined region in the first direction.

17. The structure according to claim 10, further comprising:
a second intermediate layer provided between the base body and the first intermediate layer, the second intermediate layer including Al_{z2}Ga_{1-z2}N (0<z2≤1).

18. The structure according to claim 1, wherein
the nitride member includes
a first semiconductor layer including Alₐ₁Ga₁₋ₐ₁N (0≤a1<1), and
a second semiconductor layer including Alₐ₂Ga₁₋ₐ₂N (0<a2≤1, a1<a2), and
the first semiconductor layer is provided between the stacked body and the second semiconductor layer in the first direction.

19. A semiconductor device, comprising:
the nitride structure according to claim 1;
a first electrode;
a second electrode; and
a third electrode,
the nitride member including
a first semiconductor layer including Alₐ₁Ga₁₋ₐ₁N (0≤a1<1), and
a second semiconductor layer including Alₐ₂Ga₁₋ₐ₂N (0<a2≤1, a1<a2), and
the first semiconductor layer being provided between the stacked body and the second semiconductor layer in the first direction,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

20. The device according to claim 19, further comprising:
a first insulating member including a first insulating portion, and
the first insulating portion being provided between the third electrode and the nitride member.
